(19) United States
(12) Patent Application Publication
(10) Pub. No.: US 2012/0133381 A1
(43) Pub. Date: May 31, 2012

(54) STACKABLE SEMICONDUCTOR CHIP WITH EDGE FEATURES AND METHODS OF FABRICATING AND PROCESSING SAME

(75) Inventors: Kelly BRULAND, Portland, OR (US); Timothy R. WEBB, Portland, OR (US); Andy E. HOOPER, Portland, OR (US); John R. CARRUTHERS, Beaverton, OR (US)

(73) Assignee: ELECTRO SCIENTIFIC INDUSTRIES, INC., Portland, OR (US)

(21) Appl. No.: 12/956,030

(22) Filed: Nov. 30, 2010

(51) Int. Cl. H01L 21/66; H01L 23/48; G01R 1/06

(52) U.S. Cl. 324/754.03; 257/48; 438/15; 257/E23.01; 257/E21.531

(57) ABSTRACT

A method of performing a function on a three-dimensional semiconductor chip package as well as on individual chips in the package is disclosed. That method involves the creation of an operative relationship between a function performer and an edge feature on the chip or chips wherein the edge feature consists of one or more of an electrically conductive pad, thermally conductive pad, a probe pad, a fuse, a resistor, a capacitor, an inductor, an optical emitter, an optical receiver, a test pad, a bond pad, a contact pin, a heat dissipator, an alignment marker, a metrology feature and a function performer may be any one or more of a test probe, the laser, a programming device, an interrogation device, a loading device or a tuning device. In addition, a chip per se with edge features is disclosed along with a three-dimensional stack of such chips in either of several different configurations. The disclosure provides information regarding the formation of edge feature, the singulation of dice having incipient edge features, the stacking of dice and the handling or dice with edge features.

### FIELD OF THE INVENTION

This invention relates to semiconductor chips and more particularly to the fabrication and processing of a stackable semiconductor chip having edge features which facilitate or provide access to circuitry on or in the chip.

### BACKGROUND OF THE INVENTION

Three-dimensional conductor chip packages comprising a stack of thin semiconductor chips are now being manufactured. The chips in these packages often contain controllers, memories, sensors, analog components, processors and specialty communications components as well as MEMS devices. The cost of these relatively dense, integrated packages is high, so quality control and testing as part of the fabrication, so quality control and testing as part of the fabrication process is all the more important.

Functions such as testing, trimming, bonding and tuning are typically carried out by accessing the primary surfaces of the semiconductor chips, usually a planar top surface. The accessing step may require bringing, for example, a probe into actual contact with a feature such a pad or trace on the surface. This becomes complicated or impossible when the primary surfaces of the interior chips are no longer accessible as a result of having been integrated into a stack.

### BRIEF SUMMARY OF THE INVENTION

In accordance with a first aspect of the invention, a method is provided for performing one or more functions on a semiconductor chip which is part of a stack of semiconductor chips without the necessity of contacting or otherwise addressing a top surface feature. This is achieved by providing one or more access features on a chip edge surface and, where necessary, connecting the edge feature or features to a circuit or component carried by the chip. These edge surface features remain accessible after chip stacking.

In accordance with this aspect of the invention, the function which is performed may consist of one or more testing, altering, repairing, programming, interrogating, loading and tuning as well as bonding one or more conductors into a functional relationship with a circuit or component on the chip.

Further in accordance with this first aspect of the invention, the edge feature may consist of one or more of an electrical conductor, a thermal conductor, a fuse, a resistor, a capacitor, an inductor, an optical emitter, an optical receiver, a test pad, a bond pad, a contact pin, a heat dissipation device, multiples of these and combinations of these.

Further in accordance with this first aspect of the invention, the signal conduit may consist of one or more of an electrical conductor such as a trace or a via, a heat conductor, an optical conductor, multiples of these and combinations of these.

Further in accordance with this first aspect of the invention, the method comprises the steps of locating the stack containing the semiconductor chip to be processed by way of an edge feature on a fixture wherein the edge feature can be addressed by a function performer and thereafter activating the function performer to address the edge feature. As used herein, a “chip” is a physical object with top and bottom primary surfaces, and one or more peripheral edge surface, the actual number of such edge surfaces being determined by chip geometry.

In accordance with the invention, the functions of addressing and activating may involve actual physical contact between the function performer and the edge feature but it may also be carried out in a non-contacting way particularly where the edge feature associated with the peripheral edge surface is an optical device or is recessed or buried beneath a surface of material which is transparent to the output of the function performer. The function performer may be one or more of a test probe, a wire bonder, a laser, a programmer contact, a trimmer, a data transfer contact and/or an optical transmitter or receiver and/or multiples or combinations of these elements.

In accordance with a second aspect of the invention, a stackable semiconductor chip is provided wherein the chip comprises a primary surface and has one or more devices associated with it, the definition of said devices being set forth above. This primary surface, although exposed when the die which makes up the semiconductor chip is fabricated both before and after singulation, is no longer exposed once the chip has been integrated into the three-dimensional stack. Accordingly, the die is further provided with an edge feature, the definition of which is given above as well as a signal conduit between the edge feature and the primary surface device and/or devices so that the edge feature can be used in a process as set forth above. This aspect of the invention extends to multiple chips bonded together in a stacked combination.

In accordance with a third aspect of the invention, a method of fabricating stackable semiconductor chips is provided wherein the fabrication process or method results in chips which can be processed in any of various ways by access to edge surface features after the chips have been integrated into a three-dimensional stack. As hereinafter described in detail, this process may involve the formation of layered integrated circuits in large two-dimensional arrays having what, after singulation, become edge features. During a singulation step, the buried edge features are exposed thus to provide access to a circuit or component integrated into the chips in the primary fabrication process even though the chips are assembled into a three-dimensional package of stacked chips which eliminates access to some or all of the primary surface devices in the stack.

As used herein, the terms “chip” and “die” are synonymous.

### BRIEF SUMMARY OF THE DRAWINGS

The description herein makes reference to the accompanying drawings wherein like reference numerals refer to like parts throughout the several views and wherein:

FIG. 1 is a perspective view of a pair of stacked semiconductor chips loaded on a common foundation chip embodying one or more aspects of the invention;

FIG. 2 is a perspective view of a second arrangement of stacked semiconductor chips on a foundation chip which is fixtured for alignment with a test probe;

FIG. 3 is a side view of still a third type of semiconductor chip stack embodying one or more aspects of the invention;

FIG. 4 is a partial side view of a section of a semiconductor chip illustrating various arrangements of edge surface features;

FIG. 5 is a plan view of two semiconductor chips post-singulation but prior to stacking;

FIG. 6 is a plan view of a singulated die or chip having few structures or pads as edge features;

FIG. 6a is a side view of the device of FIG. 6;

FIG. 7 is a side view of another chip stack illustrating another way to utilize edge features in the form of bonding pads;

FIG. 8 is a side view of another chip stack showing a way to perform functions thereon;

FIG. 9 is a plan view of two singulated chips in contact with one another; and

FIG. 10 is a side view of the device of FIG. 9.

### DETAILED DESCRIPTION OF THE ILLUSTRATIVE EMBODIMENTS

When semiconductor chips are bonded together in stacks, the primary surfaces of chips low in the stack are covered up. Therefore, access to features or devices on or associated with the primary surfaces is no longer possible for such functions as testing or wire bonding, or trimming or tuning or configuration change, redundancy, repair and/or encoding or programming. In accordance with the present invention, these and other functions are carried out by way of features which have been located in such a way as to be associated with one or more of the peripheral edge surfaces of the chips or dice. Thus, a die or chip which is fabricated in accordance with the present invention includes one or more edge features which facilitate or enable testing, wiring, repair, reconfiguration, tuning or processing despite the fact that the chip or die has been incorporated into a three-dimensional stack. Also disclosed herein are systems and devices to test, wire bond or otherwise process features on the edges of chips or dice in a stacked array. Also described herein is a method of performing processes on componentry or devices in stacked semiconductor dice, despite the fact that the primary surfaces with which the components or devices are associated are no longer accessible to conventional equipment.

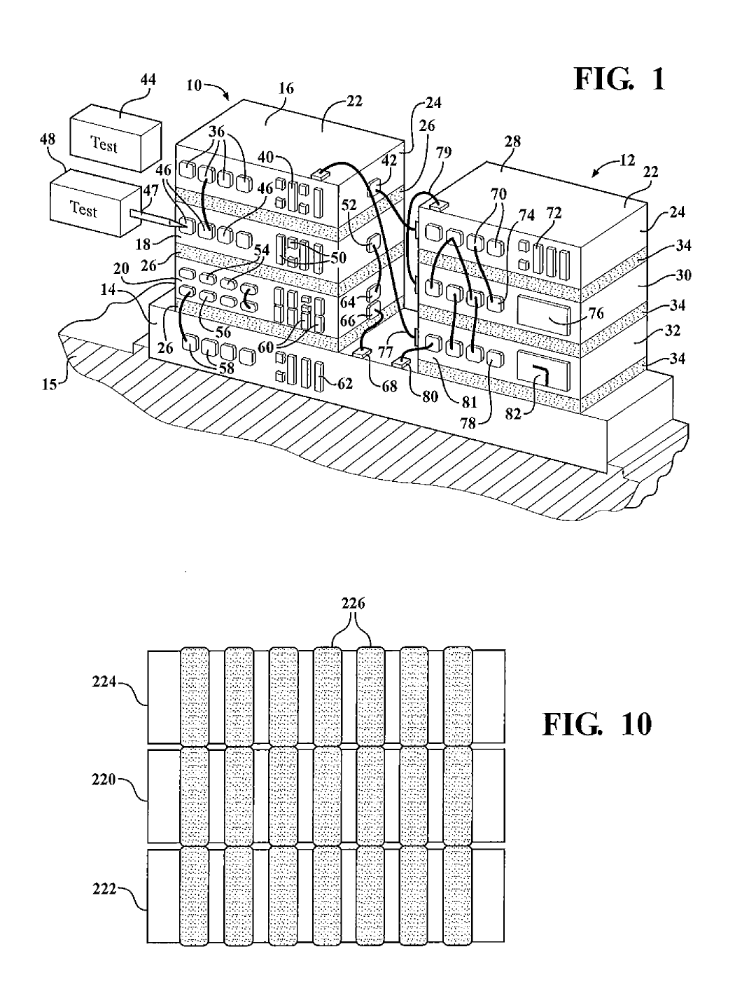

Referring to FIG. 1, there is shown a pair of three-dimensional semiconductor chip stacks 10, 12 bonded in side-by-side relationship to a semiconductor foundation chip 14. The left stack 10 comprises semiconductor chips 16, 18, and 20, each of which exhibits planar top and bottom primary surfaces as well as peripheral edge surfaces 24. In this case, because the semiconductor chips 16, 18, 20 are essentially rectangular, they each have four peripheral edge surfaces 24 but the peripheral edge surfaces can vary from one to any number depending on geometry. The chips 16, 18, 20 are adhered to one another by bonding material 26 between primary surfaces. As hereinafter described, each of the chips is presumed to carry a device or component which is associated with or exposed to one or both of the primary surface. As is apparent from an inspection of FIG. 1, some of those devices or components become inaccessible as a result of the three-dimensional stacking.

The right hand stack 12 comprises semiconductor chips 28, 30 and 32 also bonded to one another as well as to a primary surface of a foundational die 14 by bonding material 34.

The choice of three chips in each of the stacks 10, 12 is arbitrary as the number may vary from two to any practical number as will be apparent to persons skilled in the semiconductor fabrication technology.

Chip 16 exhibits edge features 36 which in this case are pads for testing or wire bonding on the surface closest to the viewer in FIG. 1 as well as alterable edge laser fuses 40. Chip 16 is also provided with an exposed pad 42 on the right hand peripheral surface 24 as shown in FIG. 1 for purposes of wire bonding. A test circuit 44 is shown wire bonded to one of the pads 36 on the top chip 16 on stack 10. In addition, the fuses 40 are shown in two different conditions; i.e., some are broken or open-circuited and others remain intact.

Chip 18 is provided on the forward peripheral edge surface with bonding or probe contact pads 46 as well as laser alterable fuses 50, the former being shown while accessed by a probe 47 which is part of a circuit test device 48. In FIG. 1, the foundation device 14 has been appropriately fixtured as at 15 so as to permit pad 46 to be accurately addressed, in this case “contacted”, by the function performer, in this case the circuit tester 48.

Die 20 is provided with electrically conductive pads 54 and fuses 60 on the foremost peripheral edge surface as well as pads 64, 66 on the right hand peripheral edge surface. The former are used for wire bonding purposes to create conductive interconnections between chips in the stack 10 as well as between the chip 20 and the foundation chip 14, the latter having bonding pads 58 associated with the foremost peripheral surface along with fuses 62. The pads 52, 64 are shown wire bonded together and the pad 66 is shown wire bonded to a pad 68 on the foundation of the chip 14. These uses and interconnections are illustrative rather than limiting.

Referring to stack 12, the foremost peripheral edge surface of chip 24 is provided with conductive pads 70 as well as laser-alterable fuses 72. The foremost peripheral edge surface of chip 30 is provided with conductive pads 74 and a trimmable structure 76; the foremost peripheral edge surface of chip 32 is provided with pads 78 and a trimmable structure such as resistive film 82. As shown, wire bonding between the pads of the stacked chips is achievable despite the lack of access to the primary surfaces. Wires such as 77, 79 can be connected between the two stacks as well as between two chips in a stack and wire 81 can be connected between one of the pads 78 on the lowermost chip 32 and the right hand stack 12 as well as to the pad 80 on a primary surface of the foundation chip 14.

Thus, FIG. 1 illustrates four different kinds of edge features; namely a wire bonding pad, a probe contact pad, a fuse, and a trimmable feature such as a resistive film. In addition, FIG. 1 illustrates the fact that the edge features may be utilized not only for testing purposes but also to create interconnections between chips in the stack as well chips in two adjacent stacks.

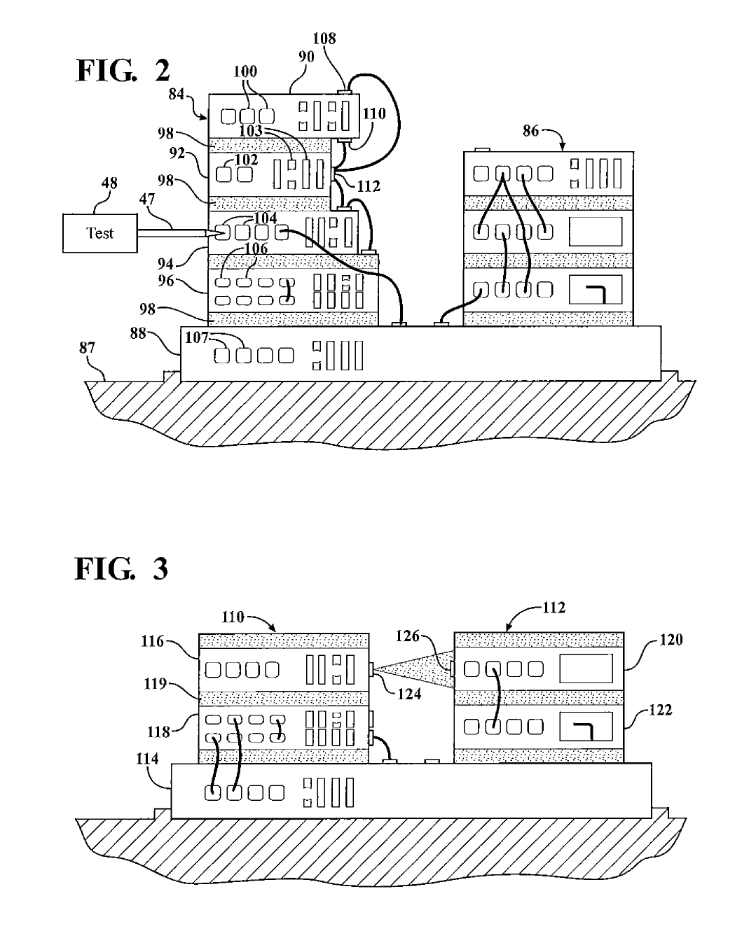

Referring now to FIG. 2, an additional design capability is illustrated, in this case by showing a four-high chip stack adjacent to a three-high chip stack 86, both stacks being bonded to a foundation chip 88 which is fixtured at 87. The left hand stack 84 comprises chips 90, 92, 94, 96, all of which are understood to carry circuit devices such as one or more of the devices described above in association with the primary surfaces, at least one of which in the case of each chip is no longer accessible by reason of the assembly of the chips into the stack 84 and the application of bonding material 98 to such primary surfaces. The top chip 90 has edge features such as conductive pads 100 as well as a primary surface feature 108 which is possible only because the top primary surface of chip 90 remains exposed. Chip 92, on the other hand, has only edge features, in this case in the form of pads 102, 112 which can be used for testing or wire bonding purposes as shown. Chip 92 also has fuses 103 as an additional edge feature.

Chip 94 has pads 104 as edge features, such pads being used in association with the probe 47 of the circuit tester 48 also shown in FIG. 1. Thus, the assembly of FIG. 2 has been properly fixtured at 87 so as to align the pads 104 in such a way as to be addressable; i.e., in this case, contacted by the probe 47 at the appropriate time when data is to be gathered and processed. Data may be gathered and processed for various purposes; e.g., for quality control or for alteration to achieve predetermined parametric goals.

Chip 96 is provided with pads 106 which in this case are used for wire bonding; i.e., FIG. 2 shows wires running between pads on the peripheral edge of chip 96 and similar pads 107 on the edge of the foundation chip 88 as well as at least one wire running between the pads on the same chip.

Stack 86 of FIG. 2 is identical to stack 12 in FIG. 1 and will not be described again in detail.

One purpose in illustrating the arrangement of FIG. 2 is to show that the invention is useful not only in stacked semiconductors packages wherein all of the chips are geometrically similar so as to fully overlap and overlie one another but also in stack arrangements wherein the chips are of different sizes thereby providing a stair step effect such that both primary and edge surface features can be utilized albeit to a lesser degree.

Referring to FIG. 3, there is shown another arrangement of stacked semiconductor chips, in this case comprising semiconductor chip stacks 110, 112 located adjacent to one another and bonded to a foundation semiconductor chip 114. Stack 110 comprises semiconductor chips 116, 118 which are essentially identical in size and geometry joined together by bonding material 119. As discussed with reference to FIGS. 1 and 2, chips 116, 118 have peripheral edge surface features, one or which is an optical transmitter 124. The other edge features are shown for purpose of illustration as probe, contact, or wire bonding pads as well as fuses so that the semiconductor chips can be interconnected among themselves as well as between themselves and the foundation chip 114.

The right hand stack 112 comprises chips 120, 122 having edge features which in this case include an optical receiver 126 on the left peripheral edge surface of chip 120. The chips 116, 120 are aligned with one another as well as adjacent so that the optical transmitter 124 is aimed essentially at the optical receiver 126 for data communication therebetween. This illustrates the fact that the operative association between edge features on the same or adjacent chips may be non-contacting.

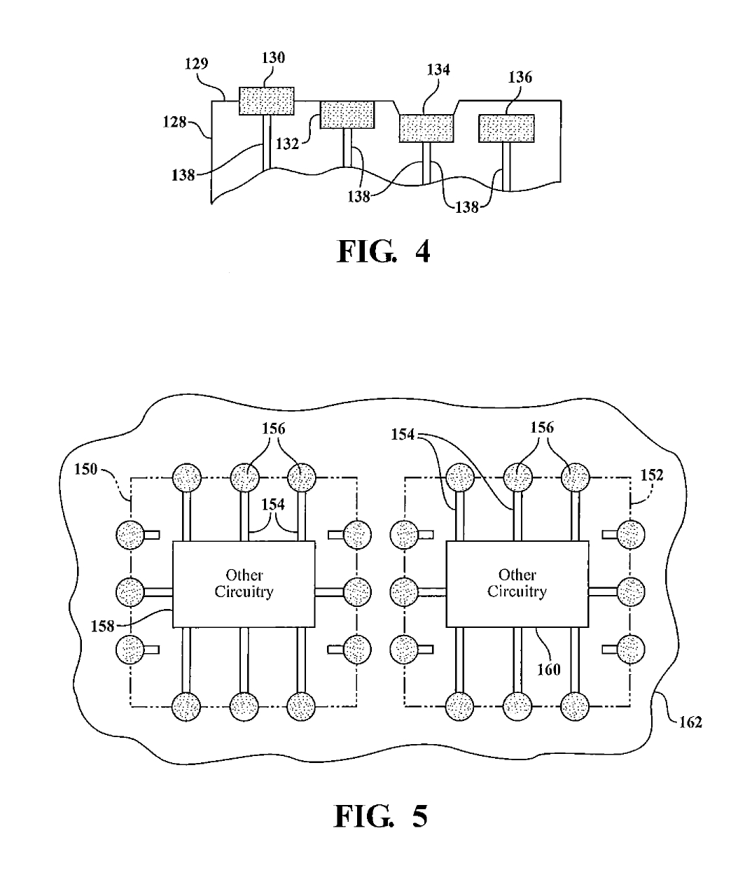

FIG. 4 illustrates still another variational aspect of the invention. In FIG. 4, reference numeral 28 denotes dielectric material in any one of the chips illustrated in FIGS. 1 through 3, the material having an exposed peripheral edge surface 129. In this case, a first edge feature in the form of a pad 130 is shown protruding above the surface 129 whereas the second edge feature in the form of a pad 136 is shown flush with the surface 129. Still a third edge feature in the form of a pad 134 is shown recessed relative to the surface 129 but still exposed for contact or wire bonding or other processing purposes. Finally, a pad 136 is shown as a subsurface feature; i.e., below the surface 129 but yet accessible for processing purposes by reason of the fact that the material 128 is transparent to whatever function is to be performed by way of access to the pad 136. Capacitive, inductive and optical couplings are examples.

FIG. 4 illustrates still another aspect which is common to the article and processing inventions disclosed herein and that is the use of signal conduits 138 between the edge features, in this case the pads 130, 132, 134, 136 and the device or devices associated with the chip which comprises material 128; i.e., the entire purpose of the edge surface feature is to provide access to the device associated with the chip and the outside world, and thus the signal conduits 138 are necessary. They may take the form of traces or other forms of electrical conductors, thermal conductors for optical conductors. However, there are instances where no such signal conduits are needed; e.g., where the edge features are alignment marks or metrology features. To catalog the edge features, they may be:
a) pads designed for contact for the probe for electrical testing;
b) pads designed for wire bonding;
c) solder bumps or terminations for electrical contacts through physical contact, solder reflow or solder reflowing;
d) protruding pins for electrical contact purposes;
e) vias that may carry information from one die through to another die;
f) structures such as fuses for redundancy repair, digital repair, encoding of information, circuit reconfiguration, encoding identification parameters, implementing and security encoding, serialization, etc.;
g) trim pads for altering impedance or tuning the value of a circuit element such as a resistor, capacitor, inductor, oscillator (isolator?) and/or other circuit elements;
h) optical devices or optical interface devices such as transmitters; e.g., lasers or LEDs; and/or receivers;
i) alignment marks and metrology features; and
j) heat dissipation features such as thermally conductive pads or heat pipes.

Accordingly one stacked die may optically transmit information to another nearby die without the need for wiring as illustrated in FIG. 3.

The subsurface feature 136 illustrated in FIG. 4 may, for example, be a metal or phase change fuse that is embedded beneath the surface of the material 120 but alterable through delivery of a laser beam. The wavelength of the light from the laser can be selected such that the die material is transparent to it; for example, a wavelength of 1.3 μm can be used with silicon. Internal trim pads are also possible.

The signal conduits, when used, may be created with vias or vertical aluminum copper or tungsten structures and may also be made with traditional lithography techniques, deep-reactive ion etching followed by refill or by laser formation followed by refill.

FIG. 5 shows a layout of two dice 150, 152 wherein the signal conduits are metal traces 154 and the edge features are shown as cylindrical vias 156. In this case, the traces 154 interconnect the edge feature vias 156 to circuitry 158, 160 on the adjacent dice 150, 152, respectively. The dice 150, 152 shown in FIG. 5 have not yet been singulated; i.e., they are all part of a larger array fabricated in a field 162 of material containing many such chips or dice of similar design. The broken lines illustrate where the edge surfaces of the dice surfaces will lie after singulation.

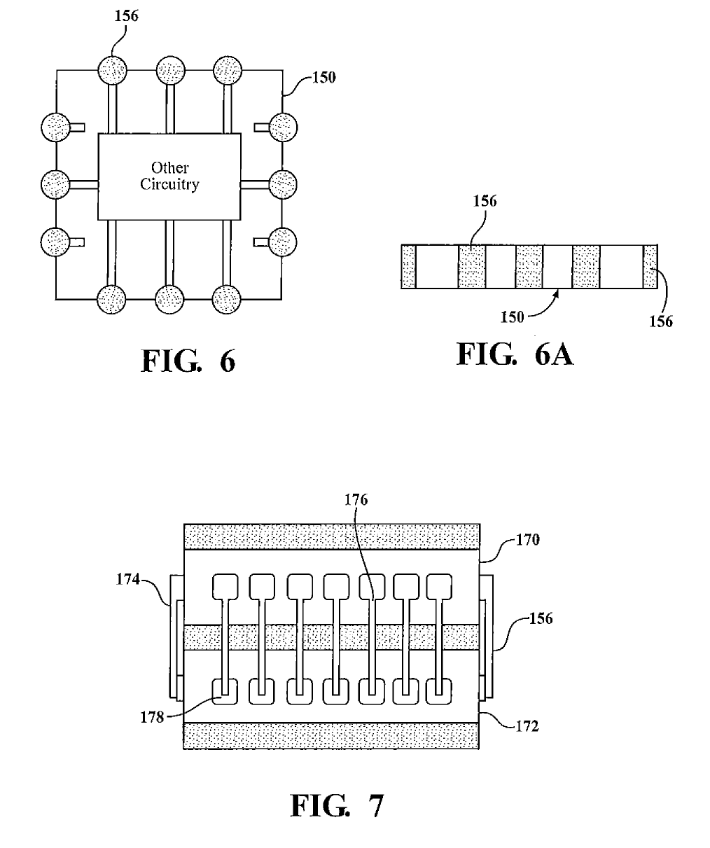

Describing the methodology of the present invention, the reference numeral 162 referred to above in connection with FIG. 5 is a wafer containing the dice 150, 152 and other dice to be with edge features here in the form of cylindrical vias 156 which are to be exposed during singulation. The wafer 162 is then processed by sawing or laser cutting and/or a combination of sawing, cutting and/or routing to define and expose the edge features, in this case, the vias 156 as shown in FIG. 6 and FIG. 6A. The edge vias 156 are now fully exposed so as to be available for processing as described.

As will be apparent to those skilled in the art, singulation can be performed by straight cuts made by way of straight cuts with a traditional saw. Alternatively, a laser can be used to make non-straight cuts to expose the edge features that are flush with the cut surface. Non-straight singulation with a laser can also be used to rout out protruding edge features or those which are slightly recessed as shown at 154 in FIG. 4. Saw cutting followed by laser routing can also be used. Lasers can also be used to make slots or slices or trim lines to expose edge features.

Another way to expose an edge feature is to perform singulation by sawing laser cuttings or scribing or braking followed by an etching which can remove material 129 surrounding the features. One preferred etch is a selected etch performed with a chemical such as XeF₂ that removes silicon at a much higher rate than metal features.

Additional structures can be added to etch features after singulation with optional edge exposure. For example, edge features can be plated, passivated, soldered or reconfigured for mechanical mating. Features can be reformed and reflowed through heating, laser, chemical or mechanical alteration. Edge features can also be added with adhesives. All of these steps can be performed before or after stacking the dice.

Referring now to FIG. 7, the disclosure turns to the discussion of stacking techniques. A die with edge features as described above can be stacked on another die or chip by picking up the die with a die-attach film already on the lower or upper surface and stacking it with or to another die in either aligned or stair step fashion as described above. The die-attach film is then cured by, for example, exposure to ultraviolet light. Similarly, an adhesive may be applied to the dies without a die-attach film and cured in the stacking process. With respect to dice or chips with edge features, care must be taken during the stacking process not to obscure or damage the edge feature with, for example, bonding materials. Contaminating the edge feature must be avoided and any contamination must be removed using an appropriate technique, such as cleaning, polishing, etching or dissolving. Laser cleaning and debris removal may also be used. Dice or chips with edge features may require alignment during the stacking and bonding process such that the edge features are properly oriented. This is preferably carried out using mechanical positioning as shown in FIGS. 1 and 2 so that the dice are in the intended locations to access edge features for additional processing steps such as wire bonding, testing or laser processing. Edge features may also require alignment to facilitate electrical connections or optical communication as described above with respect to FIGS. 1, 2 and 3.

FIG. 7 illustrates another possibility in edge alignment by crimping one die 170 on top of another die 172 where edge connectors 176 already in place mate with edge pads 178 on the lower die 172. This crimping process may also be carried out with bonding using either a die-attach film or adhesive. The electrical connections can be conductors that can be crimped together or formed using soldering or wire bonding techniques.

Bare die and stacked dice with edge features will often require automated handling techniques and these techniques must be selected so as not to damage the edge features. Handling techniques may include such devices as mechanical grippers, vacuum grippers or temporary adhesion onto a carrier plate. Grippers can be designed to allow testing access or to contain an appropriate testing interface.

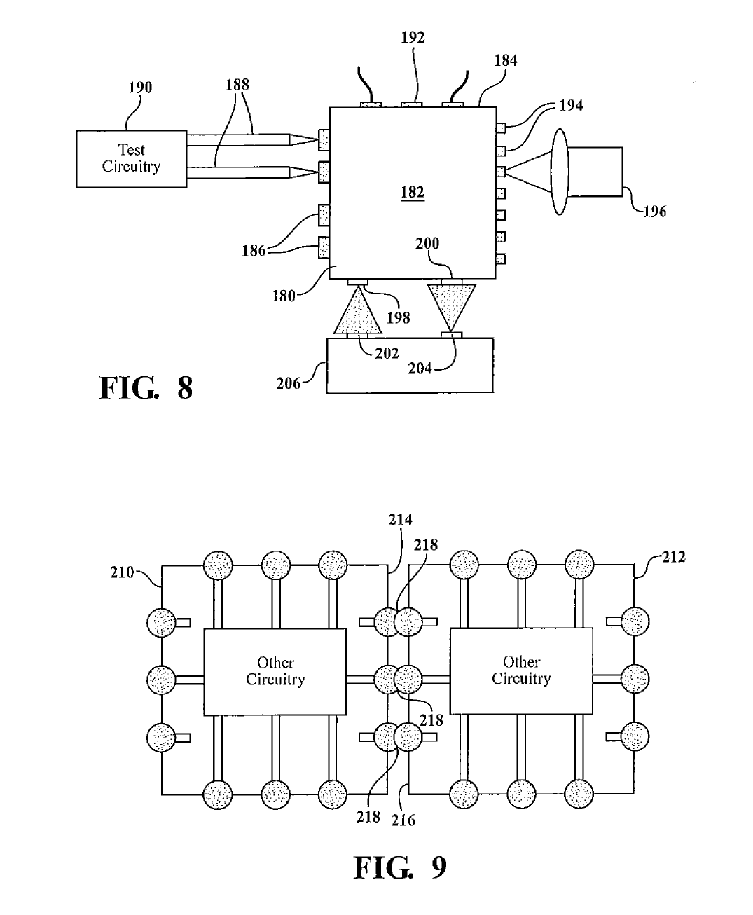

Testing or other edge function performance steps can be carried out on individual chips as well as on partial or complete stacks of chips. FIG. 8 shows a single die 180 having a primary surface 182 and four edge surfaces 184. All of the edge surfaces have edge features. By way of example, pads 186 are provided on the left peripheral edge for access by probes 188 as part of a circuit test device 190. Pads 192 are provided on another edge surface for wire bonding purposes. Features 194 are provided on another edge surface and are configured in such a way as to be repairable by a focused laser beam 196. Finally, optical communication devices 198, 200 are provided on another edge surface for appropriate communication with complemental optical devices 202, 204 on a lateral structure 206. Accordingly, multiple functions can be performed at the same time on a given die.

The discussion now turns to methods for aligning edges of chips with the edges of other chips as well as to collateral devices. It is necessary to align edge features in order to process them with laser beams, to contact them with electrical probes to perform wire bonding, to optically communicate or to otherwise interact with an edge feature. Alignment may be accomplished by aligning to the physical edges of a die, aligning to features fabricated on the edges of the due, such as bonding, pads or fuses, dedicated alignment features such as targets or ficudials that are located on the edges of the dies, aligning to structures or features located on the bottom primary surfaces of the die or aligning to other or nearby collateral structures. Alignment can be verified and modified during the alignment procedure. For example, electrical conductivity or circuit impedance can be tested and a position adjustment can be made to correct alignment. Alignment may involve determining the relative location of two different dice, thereafter the relative location of die or die features may be used to facilitate proper interfacing such as wire bonding between the two dice.

Alignment may involve using cameras or optical scans or laser scans to determine feature locations. Machine vision and vision analysis techniques can be employed. The locations of multiple dice may be determined from a single image. It may be necessary to assess and perform alignment differently on different sides of a die containing edge features. Die alignment may be optimized by assessing different sides of a die and the edge features on such dies are oriented, FIG. 8 being an example of a die with different edge features on the various peripheral edge surfaces. An optimal placement can be determined based upon the requirements of the die edges or features on the different edges.

FIG. 9 introduces the subject of how to produce edge vias and interconnect between die features.

Interconnect involving edge features may involve wire bonding of an edge feature to any other feature located on an edge, on a primary surface or on another nearby die circuit board, package conductor, foundation chip or test probe. Interconnect may be between features on a die that are stacked and/or laterally arranged.

As shown in FIG. 9, the edge features of two different dies can be brought into direct contact with one another. In FIG. 9, the edge features of dies 210, 212 located along facing edge surfaces 214, 216 have been brought into contact with one another at 218. This contact may provide communication between two dice that are located on top of one another as well as beside one another. The edge features on a center die such as die 220 shown in FIG. 10 may function as vias to transmit signals around the center die so that the lower die 222 can communicate with an upper die 224 by way of the vias 226 without communicating with the center die if that is desired.

Testing of edge structures may occur before or after stacking. Parametric tests and functional tests can be done to verify that the dice were properly fabricated. Tests may be used to sort and distribute components into bins. Following tests, additional tuning, trimming, reconfiguration, repair, serialization or identification can be performed on edge structures.

Testing, tuning and trimming and repairing with edge structures can be also used to determine and/or correct for changes and defects during the packaging process. For example, it may be required to tune the electrical impedance to properly mate one die to a different die. Packaging effects can be mitigated using edge tests or alterations.

Some of the testing, trimming and tuning can be based on properties in the die that are measured before they are stacked. Testing during a die stacking may reveal that the die is cracked or has undergone irreparable damage during handling. Such a die can be removed and replaced with an undamaged substitute. Alternatively, this stack of dice can be discarded before any additional undamaged dies are added by bonding or otherwise. Testing with edge structures can also be used as part of a reliability test, a burn-in and/or during final testing of stacked dies.

FIGS. 1 and 2 illustrate in schematic terms what is needed to perform some types of testing. A fixture adapted to receive dice of a certain configuration and of a predetermined edge feature type is provided. That fixture automatically aligns dice of appropriate geometry and edge configuration arrangement with function performing devices such as test probes so that the function performing devices properly address the edge features in space. Thereafter, the function performing devices can be activated; i.e., advanced into contact or into near proximity or simply turned on as necessary to produce a functional relationship with the edge feature being addressed. Data can be collected as necessary and decisions made regarding the viability, operability and/or alteration made in or to the edge feature.

It will be appreciated that the embodiments illustrated in the drawing and described above are exemplary and that implementation of the invention can be carried out in various other configurations.

What is claimed is:

1. A method of performing a function on a semiconductor chip which is part of a stack of semiconductor chips wherein said chip has a primary surface and one or more peripheral edge surfaces, a device associated with the primary surface and an edge feature associated with the edge surface wherein:
the function consists of one or more of testing, altering, repairing, programming, interrogating, loading, tuning and data exchange;
the device consists of one or more of a circuit, circuit component, memory and controller;
the edge feature consists of one or more of an electrical conductor, a thermal conductor, a fuse, a resistor, a capacitor, an inductor, an optical emitter, an optical receiver, a test pad, a bond pad, a contact pin, a heat dissipator, alignment marks, and metrology features;
wherein the method comprises the steps of:
(a) locating the stack such that the edge feature can be accessed by a function performer; and
(b) activating the function performer to access the device via the edge feature.

2. The method of claim 1 wherein the function performer is a test probe.

3. The method of claim 1 wherein the function performer is a wire bonder.

4. The method of claim 1 wherein the function performer is a laser.

5. The method of claim 1 wherein the function performer is a programmer contact.

6. The method of claim 1 wherein the function performer is a trimmer.

7. The method of claim 1 wherein the function performer is a data transfer contact.

8. The method of claim 1 wherein the function performer is an optical transmitter.

9. The method defined in claim 1 wherein the chip is also provided with a signal conduit connecting the device to the edge feature.

10. The method of claim 9 wherein the signal conduit is one or more of an electrical conductor, a thermal conductor and/or an optical conductor.

11. A method of testing an integrated circuit chip of the type comprising a dielectric body carrying at least one circuit device, said chip having a primary surface and at least one peripheral edge surface, at least one probe pad associated with said peripheral edge surface and electrically connected to the circuit device comprising the steps of:
bringing a test probe into contact with the test pad; and
generating data derived from the contact of the test probe with the test pad.

12. A method of tuning or otherwise altering circuitry on an integrated circuit chip of the type comprising a dielectric body having a primary surface and at least one peripheral edge surface, said circuitry being at least associated with said primary surface, said chip further having an alterable circuit component on said edge surface and connected by a signal conduit to the circuitry comprising the steps of:
mounting the integrated circuit in a fixture such that an external device can address the component; and
operating the external device to alter the component on the peripheral edge surface.

13. A three-dimensional semiconductor device comprising:
first and second stacked integrated circuit chips, each said chip comprising a body of dielectric material having a primary surface and at least one peripheral edge surface, at least one of the chips having circuitry disposed on a primary surface which is overlaid by a primary surface of the other chip in the stack, at least one said chip having a conductor test pad disposed on the peripheral edge surface of the chip and electrically connected to the circuitry on the primary surface of the chip;
whereby the circuitry on at least said one chip can be tested by means of a test probe contacting the test pad.

14. A method of fabricating an integrated circuit chip which is adapted to be stacked with other similar integrated circuit chips in a three-dimensional array and tested while in the stacked array comprising the steps of:
(a) forming circuitry on or in the chip;
(b) placing a test pad on a peripheral edge surface of the chip, and
(c) electrically connecting the test pad to the circuitry on or in the chip.

15. A method of fabricating a three-dimensional semiconductor chip stack comprising a plurality of individual semiconductor dice comprising the steps of:
constructing a two-dimensional array of semiconductor dice in a dielectric field material wherein each die has an exposed primary surface, a device associated with said primary surface, at least one buried edge feature and a signal conduit interconnecting the device with the buried edge feature;
singulating the dice to create peripheral edge surfaces and expose said buried edge features; and
combining dice in a stack so as to de-expose at least some primary surfaces.

16. A method of testing a device on an integrated circuit chip located in a stack of semiconductor chips wherein each chip has a primary mounting surface for one or more integrated circuit devices, at least one peripheral edge surface intersecting the primary surface, and a test probe contact pad on the edge surface and electrically connected to the device on the primary surface, said method comprising the steps of:
placing the stack on a test fixture so as to align the pad with a test probe; and
causing the test probe to come into contact with the pad.
